(19) United States
(12) Patent Application Publication
(10) Pub. No.: US 2026/0312159 A1
(43) Pub. Date: Oct. 8, 2026

(54) Method and Devices for Operating Deep Discharge-Proof Battery Packs for Electric Processing Tools

(71) Applicant: Andreas Stihl AG & Co. KG, Waiblingen (DE)

(72) Inventors: Christian UHLMANN, Erlangen (DE); Florian Klein, Esslingen am Neckar (DE)

(21) Appl. No.: 19/462,146

(22) Filed: Jan. 28, 2026

(30) Foreign Application Priority Data
Jan. 29, 2025 (DE) 10 2025 103 179.7
Feb. 5, 2025 (DE) 10 2025 104 196.2
Feb. 17, 2025 (DE) 10 2025 105 891.1

(51) Int. Cl. H01M 10/44; G01R 31/3842; G01R 31/389; G01R 31/392; H01M 10/054; H01M 10/48; H02J 7/44; H02J 7/90

(52) U.S. Cl. CPC H01M 10/448; G01R 31/3842; G01R 31/389; G01R 31/392; H01M 10/054; H01M 10/486; H01M 10/488; H02J 7/44; H02J 7/933

(57) ABSTRACT

A method identifies a state of deep discharge of at least one electric battery cell of an electric battery pack by way of an identification device. The battery pack has two poles, at which an electric pole voltage of the battery pack, which voltage is dependent upon an electric cell voltage of at least one electric battery cell, can be tapped. The at least one battery cell is configured for a reversible transition between the state of deep discharge and a charged state of the at least one battery cell. The method has the following steps: aa) capturing a value of the electric pole voltage of the battery pack in the event that the value of the electric pole voltage captured in conjunction with the execution of step aa) lies within a stipulated range around 0 V; and identifying the state of deep discharge of the at least one battery cell by way of the identification device.

### CROSS REFERENCE TO RELATED APPLICATIONS

This application claims priority under 35 U.S.C. § 119 from German Patent Application Nos. 10 2025 103 179.7, filed Jan. 29, 2025, 10 2025 104 196.2, filed Feb. 5, 2025, and 10 2025 105 891.1, filed Feb. 17, 2025, the entire disclosures of which are herein expressly incorporated by reference.

### FIELD OF APPLICATION AND PRIOR ART

The invention relates to devices and methods for operating deep discharge-proof battery packs for electric processing tools. The invention is based upon the observation to the effect that the operation of deep discharge-proof battery packs introduces new potential applications and challenges associated with the operation of electric processing tools.

Accordingly, a first aspect of the invention relates to a method for identifying a state of deep discharge of at least one electric battery cell of an electric battery pack with the support of, in particular by means of an identification device. The first aspect of the invention further relates to an electric battery pack for an electric processing system, and to an electric processing system of this type. The first aspect of the invention further relates to an electric charging device, or to a battery-electric electrical processing tool for an electric processing system of this type.

A second aspect of the invention relates to a method for the deep electric discharging of at least one deep discharge-proof electric battery cell of a battery pack by means of an electric discharging device. The second aspect of the invention further relates to a battery pack for a method of this type. The second aspect of the invention moreover relates to an electric processing tool, to an electric charging device, and to a system.

A third aspect of the invention relates to a method for the electric charging of a battery pack, and to an electric battery pack of this type. The third aspect of the invention moreover relates to an electric charging device for the electric charging of a battery pack. The third aspect of the invention further relates to an electric system. The third aspect of the invention moreover relates to an employment of at least one deep discharge-proof battery cell in an electric battery pack, and/or to an employment of an electric battery pack of this type, and/or to the employment of an electric charging device, and/or to the employment of an electric system.

### First Aspect of the Invention

One object of the first aspect of the present invention is the provision of a method for identifying a state of deep discharge of at least one electric battery cell of an electric battery pack by means of an identification device, of an electric battery pack for an electric processing system, of an electric processing system of this type, and of an electric charging device and/or a battery-electric electrical processing tool for an electric processing system of this type, each of which in particular assumes specific, and particularly improved properties. In particular, it is intended that the state of deep discharge should be externally identifiable, in particular for a third party, in particular by way of evidence for transport purposes, in particular for transport by air freight, and/or for recycling purposes, and/or for storage purposes.

A method according to the first aspect of the invention is employed for identifying a state of deep discharge of at least one electric battery cell of an electric battery pack by means of an identification device. Appropriately, according to the method, the state of deep discharge of the at least one electric battery cell of the electric battery pack is identified by means of the identification device. In particular, according to the method, by means of the identification device, it can be identified that the at least one battery cell of the battery pack presently assumes a state of deep discharge, or otherwise. The battery pack has two electric poles. The two poles can be embodied as electric terminals of the battery pack. The two poles are configured such that an electric pole voltage of the battery pack can be tapped at the poles. In particular, the pole voltage is defined by a potential difference between the poles. In particular, the pole voltage can only be tapped at the poles in the event that this voltage differs from 0 V (volts). The electric pole voltage of the battery pack is dependent upon an electric cell voltage of the at least one electric battery cell of the battery pack. The at least one battery cell is configured for reversible transition between the state of deep discharge and a charged state of the at least one battery cell. In the present context, the term “reversible” signifies that the battery cell is capable of undergoing at least ten, particularly at least 100, and more particularly at least 1,000 transition cycles between the state of deep discharge and the charged state. Alternatively or additionally, the term “reversible” can signify the stable assumption by the battery cell of a state of deep discharge, such that the battery cell can be maintained for a prolonged period and/or stored in the state of deep discharge. The battery cell can be configured, in multiple cycles, to execute an alternating transition from the state of deep discharge to the charged state, by the charging thereof with electrical energy, and thereafter to execute a transition from the charged state back to the state of deep discharge, by the tapping of charged electrical energy. In particular, the at least one battery cell, in the state of deep discharge, is classified as essentially de-energized. The at least one electric battery cell, in the state of deep discharge, in particular, can be de-energized and/or physically short-circuited. In other words: the battery cell can assume the state of deep discharge, in the event of the de-energized state thereof.

The method according to the first aspect of the invention comprises a step aa), according to which a capture of the electric pole voltage of the battery pack is executed. The term “capture” can signify “tapping”. The method further comprises a step ba), according to which—in the event that the electric pole voltage captured by the execution of step aa) lies within a stipulated range around 0 V—an identification of the state of deep discharge of the at least one battery cell is executed by means of the identification device. In particular, step ba) can comprise a detection of the state of deep discharge of the at least one battery cell on the basis of the pole voltage thus captured.

In this manner, by means of the identification device, an external identification, in particular for a third party, is enabled to the effect that the at least one electric battery cell of the battery pack presently assumes a state of deep discharge and/or is de-energized. This identification can be employed, in particular vis-à-vis the third party, by way of evidence to the effect that a particularly simple transport of the battery pack can be executed, particularly via air freight, which transport requires no particular precautions. It can likewise be externally confirmed, in particular to a third party, that a storage and/or recycling of the battery pack is enabled, in particular with no particular precautions.

Appropriately, in the present context, the term “with the support of” can be understood in the sense of “by means of”.

The method can appropriately comprise a monitoring of an interim charging of the battery cell. In the event that such an interim charging is detected, identification of the state of deep discharge according to step ba) can be revised, particularly in order to counteract any spurious identification. The term “interim charging” can signify an interim charging and/or an interim charge.

The pole voltage can be dependent upon the electric cell voltage of all the battery cells of the battery pack, particularly in the event that the battery cells of the battery pack, vis-à-vis the poles of the battery pack, are arranged in a parallel electric circuit or in a serial electric circuit. In one configuration of the first aspect of the invention, upon the execution of step ba), it can be identified that all the battery cells of the battery pack assume the state of deep discharge, in the event that the electric pole voltage captured in conjunction with the execution of step aa) lies within the stipulated range around 0 V.

Appropriately, it is contemplated that one group of electrically parallel-connected battery cells is electrically arranged in series with another group of electrically parallel-connected battery cells. Alternatively or additionally, it is also contemplated that one group of electrically series-connected battery cells is electrically arranged in parallel with another group of electrically parallel-connected battery cells. Alternatively or additionally, composite arrangements are optionally contemplated. Limits of the range around 0 V can be dependent upon the mutual interconnection of battery cells.

According to a further configuration of the first aspect of the invention, for each execution of step aa), a pole voltage value is determined for the pole voltage. Alternatively or additionally, step aa) is executed twice, in particular three times, and more particularly ten times, within a time interval of 1 s (second), in particular of 5 s, more particularly of 1 min (minute), and further particularly of greater than 1 min, wherein the state of deep discharge is only identified in the event that all the pole voltage values thus determined lie within the stipulated range around 0 V.

Appropriately, the term “determination” can be understood in the sense of “ascertainment” and/or “measurement”.

According to a further configuration of the first aspect of the invention, in particular, pole voltage values for the pole voltage thus determined are recorded and evaluated, in order to confirm the permanent, or only temporary assumption by the pole voltage of a value within the stipulated range around 0 V. In this manner, a particularly meaningful identification of the state of deep discharge can be executed.

According to a further configuration of the first aspect of the invention, the identification device, in particular as a component of the battery pack, is permanently electrically connected to the at least one battery cell of the battery pack. Accordingly, the method can be executed in a particularly practicable manner, particularly on the grounds that the method can be executed using the battery pack only, in particular with no additional equipment. In particular, the identification device of the battery pack is electrically connected to the poles of the battery pack.

According to a further configuration of the first aspect of the invention, the battery pack, for the execution of step aa), is detachably electrically connected to a battery-electric processing tool. The battery-electric processing tool thus comprises an, in particular the identification device, or a further identification device. In particular, the battery pack can thus assume no dedicated identification device, or can assume a dedicated identification device, in particular additionally to that of the processing device. The battery-electric processing tool can be battery-electric-operated.

According to a further configuration of the first aspect of the invention, the battery pack, for the execution of step aa), is detachably electrically connected to an electric charging device for the electric charging of the at least one battery cell of the battery pack. It is contemplated that the charging device assumes a dual function wherein, additionally to the charging function thereof, it functions as a means of carriage, in particular of a tray-type design, for the battery pack or, optionally, for multiple battery packs.

It is contemplated that the identification device is embodied by means of an on-line identification function. For example, the battery pack can be connected in a data transfer arrangement, particularly wirelessly, to an online cloud for the online identification function. It is further contemplated that a release for the recharging of a battery pack which presently assumes a state of deep discharge, in particular, can only be issued by means of the online cloud. For example, for the wireless connection of the battery pack to the online cloud, a wireless standard such as Bluetooth, or similar, can be employed.

According to a further configuration of the first aspect of the invention, the charging device comprises the identification device, or communicates with the identification device, for the identification of the state of deep discharge. In the first case, the battery pack can assume no dedicated identification device, or can additionally comprise a dedicated, in particular a redundant identification device. In the second case, the identification device can be provided by the battery pack, or can be configured as a separate identification device, in particular as a standalone identification device.

According to a further configuration of the first aspect of the invention, the state of deep discharge is identifiable by means of an electrically controllable display device of the identification device. The display device of the identification device can comprise an electrophoretic display and/or at least one LED (light-emitting diode).

The battery pack can appropriately comprise an additional auxiliary electric energy storage device which is independent of the at least one battery cell thereof, particularly in the form of an electric button cell or similar, which auxiliary electric energy storage device is configured for supplying the display device of the battery pack with electrical energy. In this manner, an operation of the display device of the battery pack can be enabled, even in the event that the at least one electric battery cell of the battery pack is not able to supply energy, on the grounds of the assumption thereof of a state of deep discharge, in particular a de-energized state.

It is understood that the above-mentioned auxiliary energy storage device can be obsolete, in the event that the display device is configured for the passive and/or off-circuit display of the state of deep discharge, and that, correspondingly, the display status thereof is maintained, particularly in a continuous manner, even in the absence of an energy supply and/or pending the restoration of the energy supply. Correspondingly, the battery pack can optionally be configured with no auxiliary energy storage device. The same can also apply to the implementation of the online identification function.

The battery pack and/or the identification device can appropriately comprise an RFID and/or an NFC chip.

Under certain circumstances, it is appropriately contemplated that the identification device is embodied in the form of a potentiometric dye indicator.

According to a further configuration of the first aspect of the invention, the method comprises a step ca), according to which a check is executed of an electrical connection between the at least one battery cell and the identification device. In this manner, a spurious detection of a state of deep discharge of the at least one battery cell associated with an interruption of at least one electrical conductor in the interior of the battery pack can be counteracted in the event that, as a result of this interruption, the dependence of the pole voltage upon the cell voltage is eradicated and/or impaired such that, in practice, the at least one electric battery cell does not presently assume a deep state of discharge, notwithstanding a pole voltage within the range around 0 V.

According to a further configuration of the first aspect of the invention, the stipulated range around 0 V extends from −1 V to 1.5 V, particularly from 0 V to 1 V, and more particularly from 0 V to 0.1 V. Appropriately, for the stipulated range around 0 V, the limiting values thus indicated, and which differ from 0 V, are not included in the range. Alternatively or additionally, the stipulated range around 0 V can be defined such that the lower limiting value thereof corresponds to 0 V, or is lower than 0 V, whereas the upper limiting value thereof lies below a stipulated end-of-discharge voltage value, in particular of other and/or of conventional battery cell types. In particular, the above-mentioned values apply to individual cells such that, depending upon the number of battery cells and/or the interconnection thereof, optionally, ranges having quantitatively higher limiting values can also be generated.

Appropriately, identification according to step ba) can only be executed in the event that the value of the electric pole voltage is equal to or lower than a stipulated end-of-discharge voltage value of the battery pack. The end-of-discharge voltage value can be defined as 1.5 V, in particular even as 0 V.

In some cell types, further to short-term deep discharging, a voltage relaxation can occur, as a result of which a further rise in the pole voltage is automatically generated. A voltage relaxation of this type can be at least partially counteracted, wherein the state of deep discharge of the battery cell is maintained over a longer term, in particular for a stipulated time interval. Correspondingly, in the present context, it can be appropriate to monitor a maintenance time of the state of deep discharge. Optionally, identification according to step ba) can only be executed in the event that the maintenance time at least corresponds to the stipulated time interval.

An electric battery pack according to the first aspect of the invention is designed for employment in an electric processing system, which system comprises a battery-electric processing tool which is configured to operate by means of electrical energy which is stored in the battery pack, and/or an electric charging device which is configured for charging the battery pack with electrical energy. The battery pack for the processing system is thus configured for executing a method according to the first aspect of the invention, as described above. The battery pack according to the first aspect of the invention thus comprises two poles, at which an electric pole voltage of the battery pack, which voltage is dependent upon an electric cell voltage of at least one electric battery cell of the battery pack, can be tapped, wherein the at least one battery cell of the battery pack is configured for a reversible transition between the state of deep discharge and a charged state of the at least one battery cell. In the state of deep discharge, the electric pole voltage lies within a stipulated range around 0 V. In the charged state, the electric pole voltage exceeds the stipulated range around 0 V.

According to a further configuration of the first aspect of the invention, the at least one electric battery cell of the battery pack is deep discharge-proof and/or is configured as electrically reversible. The term “deep discharge-proof” can signify “stable vis-à-vis a deep discharge”. Alternatively or additionally, the at least one and, in particular, each battery cell of the battery pack can be selected from the group comprised of the following: sodium-ion battery cells, in particular having an aprotic and, more particularly, having a fluid electrolyte; solid-state electrolyte battery cells, in particular having lithium ions and/or having sodium ions; lithium-ion battery cells having copper-free current collectors, in particular having non-metallic current collectors and/or having no anode and/or having a lithium metal electrode. Such cell types can be particularly stable and/or robust in response to cyclical deep discharging.

Appropriately, in the present context, the term “deep discharge” can be understood as a state proceeding from the tapping of current up to the achievement of a virtually complete transfer of current carriers from a negative pole (anode) to a positive pole (cathode) of the cell, or up to the achievement of a very low residual quantity of electrochemical energy. Alternatively or additionally, the term “deep discharge” can be understood as a state proceeding from the tapping of current to the undershoot of a specific electric voltage, which voltage corresponds to an end-of-discharge voltage of conventional battery cells. By way of particular distinction from conventional battery cell types, in battery cells of the battery pack according to the first aspect of the invention, a singular and, in particular, multiple deep discharging is enabled, with no functional impairment.

Alternatively or additionally, reference can appropriately be made to presently widespread and colloquial definitions, c.f. https://de.wikipedia.org/wiki/Tiefentladung (deep discharge) and https://de.wikipedia.org/wiki/Elektrische_Kapazität (electrical capacity)—each in the version thereof as at Jan. 15, 2025. According thereto, the term “deep discharge” can be understood as a state proceeding from the tapping of current up to a near-exhaustion of capacity or up to the achievement of a specific voltage—with the proviso that, in the case of accumulators and batteries, the term “capacity” can be employed to describe the maximum quantity of charge which can be stored therein. This “capacity”, which is expressed in ampere-hours (represented by the symbol Ah), bears no relation to electrical capacitance, which is a physical variable employed in the field of electrostatics.

Appropriately, the at least one battery cell of the battery pack can be configured, with no breakdown of the cell components thereof, in particular of the cell electrodes thereof, to undergo a deep discharge. Alternatively or additionally, at least one of the cell electrodes of the at least one battery cell of the battery pack can incorporate a graphite material, or can be comprised of such a graphite material.

Appropriately, the at least one electric battery cell of the battery pack has at least one and, in particular, only one copper-free current collector, i.e. cell electrode(s).

Appropriately, the at least one battery cell of the battery pack, which cell is configured for reversible deep discharging, is a solid-state battery cell. A solid-state battery of this type, in particular, comprises electrolytes which, under standard conditions, are solid.

It can be appropriate that none of the electric battery cells of the battery pack is a lithium-ion battery cell. Alternatively or additionally, in particular, none of the battery cells of the battery pack is a nickel-metal hydride battery cell. In other words: it can be appropriate that the at least one battery cell of the battery pack corresponds to a cell type, which cell type differs from lithium-ion battery cells and/or from nickel-metal hydride battery cells.

Appropriately, the battery pack is an electric accumulator pack. The at least one battery cell can be an electric accumulator cell.

An electric processing system according to the first aspect of the invention comprises a battery pack according to the first aspect of the invention, as described above. The processing system moreover comprises a battery-electric processing tool, which tool is configured for executing a method according to the first aspect of the invention, as described above. Alternatively or additionally, the electric processing system comprises an electric charging device, which device is configured for executing a method according to the first aspect of the invention, as described above.

An electric charging device according to the first aspect of the invention and/or a battery-electric electrical processing device according to the first aspect of the invention is configured for employment in an electric processing system according to the first aspect of the invention, as described above.

For the method, it is contemplated that the identification device is a component of the battery pack itself, a component of a charging device, a component of a processing device, or a standalone identification device. Alternatively or additionally, it can be contemplated that the identification device is implemented online, in particular for the execution of the above-mentioned online identification function.

In the event that the battery pack comprises multiple electric battery cells, under certain circumstances, it can be appropriate that the cell voltage of each individual battery cell is considered separately, within the meaning of the method, as a dedicated pole voltage, particularly wherein each cell voltage is monitored in an individual manner.

### Second Aspect of the Invention

One object of the second aspect of the present invention is a provision of a method for the deep electric discharge of at least one deep discharge-proof electric battery cell of a battery pack by means of an electric discharging device, a battery pack for a method of this type, an electric processing tool, an electric charging device and a system, each of which in particular assumes specific, and particularly improved properties. In particular, it is intended that a particularly reliable deep discharging of at least one deep discharge-proof electric battery cell should be enabled.

A method according to the second aspect of the invention is particularly employed for the reliable deep electric discharging of at least one deep discharge-proof electric battery cell of a battery pack by means of an electric discharging device. Appropriately, according to the method, the at least one deep discharge-proof electric battery cell of the battery pack undergoes deep discharge by means of an electric discharging device. The method comprises a step ab), according to which a switch-on of the discharging device is executed such that an electric discharging current flows through the switched-on discharging device. The discharging current can be based upon an electric cell voltage of the at least one deep discharge-proof battery cell, and/or upon a voltage of the discharging device, for example of an additional voltage or counter-voltage, in order to accelerate or slow down the discharge process as required. The method further comprises a step bb), according to which a check is executed as to whether the discharging current falls below a stipulated level. In particular, on the basis of this check, a reduction of the discharging current below the stipulated level can be detected. In this manner, it can be reliably detected that the at least one deep discharge-proof electric battery cell has executed a transition to a state of deep discharge. In particular, the check as to whether the discharging current falls below a stipulated level, alternatively or additionally, can be executed by means of the electric cell voltage of the at least one deep discharged battery cell, a voltage of the battery pack or a pack voltage, and/or a time criterion.

The method can further comprise a step, according to which a detection or confirmation of the at least one battery cell as deep discharge-proof is executed. In particular, the term “detection or confirmation as deep discharge-proof” can be understood to the effect that a detection is executed as to whether the at least one battery cell enables a reversible transition thereof to a state of deep discharge. Detection or confirmation can be executed by reference to predefined characteristic curves and/or by means of a battery management system of the battery pack, and/or by reference to information which is assigned to the battery pack and/or to the battery cell, wherein the information identifies the at least one battery cell as deep discharge-proof. Information can be exemplarily communicated via an interface, and/or retrieved and/or captured.

The method can enable a particularly protective deep discharging of the deep discharge-proof battery cell. Alternatively or additionally, the method can enable a reliable transition of the battery cell to a stable state of deep discharge.

Appropriately, in the present context, the term “with the support of” can be understood in the sense of “by means of”.

Appropriately, in the present context, the term “deep discharge-proof” can be understood as “stable vis-à-vis a deep discharge”.

Appropriately, the deep discharge-proof battery cell is configured to execute a reversible transition between a state of deep discharge and a charged state. The term “reversible” can signify that the battery cell can undergo at least 10, in particular at least 100 and, more particularly, at least 1,000 transition cycles between the state of deep discharge and a charged state of the battery cell. Alternatively or additionally, the term “reversible” can signify the stable assumption by the battery cell of a state of deep discharge, in particular such that the battery cell can be maintained for a prolonged period and/or stored in the state of deep discharge. The battery cell can be configured, in multiple sequential cycles, to execute an alternating transition from the state of deep discharge to the charged state, by the charging thereof with electrical energy, and thereafter to execute a transition from the charged state back to the state of deep discharge, by the tapping of charged electrical energy. In particular, the at least one battery cell, in the state of deep discharge, is classified as essentially de-energized. The at least one electric battery cell, in the state of deep discharge, in particular, can be de-energized and/or physically short-circuited. In other words: the battery cell can assume the state of deep discharge, in the event of the de-energized state thereof.

Appropriately, the at least one deep discharge-proof battery cell can be configured as electrically reversible.

Appropriately, the battery pack can comprise two, or more than two deep discharge-proof battery cells.

Appropriately, the at least one and, in particular, each deep discharge-proof battery cell of the battery pack can be selected from the group comprised of the following: sodium-ion battery cells, in particular having an aprotic and, more particularly, having a fluid electrolyte; solid-state electrolyte battery cells, in particular having lithium ions and/or having sodium ions; lithium-ion battery cells having copper-free current collectors, in particular having non-metallic current collectors and/or having no anode and/or having a lithium metal electrode. Such cell types can be particularly stable and/or robust in response to cyclical deep discharging.

Appropriately, in the present context, the term “deep discharge” can be understood as a state proceeding from the tapping of current up to the achievement of a virtually complete transfer of current carriers from a negative pole (anode) to a positive pole (cathode) of the cell, or up to the achievement of a very low residual quantity of electrochemical energy. Alternatively or additionally, the term “deep discharge” can be understood as a state proceeding from the tapping of current to the undershoot of a specific electric voltage, which voltage corresponds to an end-of-discharge voltage of conventional battery cells. By way of particular distinction from conventional battery cell types, in battery cells of the battery pack according to the second aspect of the invention an, in particular, multiple deep discharging is enabled, with no functional impairment.

Alternatively or additionally, reference can appropriately be made to presently widespread and colloquial definitions, c.f. https://de.wikipedia.org/wiki/Tiefentladung (deep discharge) and https://de.wikipedia.org/wiki/Elektrische_Kapazität%C3%A4t (electrical capacity)—each in the version thereof as at Jan. 15, 2025. According thereto, the term “deep discharge” can be understood as a state proceeding from the tapping of current up to a near-exhaustion of capacity or up to the achievement of a specific voltage—with the proviso that, in the case of accumulators and batteries, the term “capacity” can be employed to describe the maximum quantity of charge which can be stored therein. This “capacity”, which is expressed in ampere-hours (represented by the symbol Ah), bears no relation to electrical capacitance, which is a physical variable employed in the field of electrostatics.

Appropriately, the at least one battery cell of the battery pack can be configured, with no irreversible breakdown of the cell components thereof, in particular of the cell electrodes thereof, to undergo a deep discharge. Alternatively or additionally, at least one of the cell electrodes of the at least one battery cell of the battery pack can incorporate a graphite material, or can be comprised of such a graphite material.

Appropriately, the at least one electric battery cell of the battery pack has at least one and, in particular, only one copper-free current collector, i.e. cell electrode(s).

Appropriately, the at least one battery cell of the battery pack, which cell is configured for reversible deep discharging, is a solid-state battery cell. A solid-state battery of this type, in particular, comprises electrolytes which, under standard conditions, are solid.

It can optionally be appropriate that none of the electric battery cells of the battery pack is a lithium-ion battery cell. Alternatively or additionally, in particular, none of the battery cells of the battery pack is a nickel-metal hydride battery cell. In other words: it can be appropriate that the at least one battery cell of the battery pack corresponds to a cell type, which cell type differs from lithium-ion battery cells and/or from nickel-metal hydride battery cells.

In particular, conventional battery cells, by way of distinction from the at least one deep discharge-proof battery cell, cannot undergo a deep discharge, in particular not to a cell voltage of 0 V, on the grounds that, in conventional battery cells, ageing processes and functionally critical reactions (for example, dissolution of copper at the anode) would otherwise occur. Correspondingly, conventional battery cells, customarily, are only discharged to the extent that, even in a “discharged” state, a residual energy content remains in the conventional battery cell, which residual energy content is potentially problematic, particularly with respect to storage and/or with respect to transport, particularly by air freight.

Appropriately, the battery pack is an electric accumulator pack. The at least one battery cell can be an electric accumulator cell.

According to one configuration of the second aspect of the invention, the switch-on according to step ab) comprises a switch-in of an electrical resistor element. Optionally, the switch-on according to step ab) can be executed exclusively by the switch-in of the resistor element. The electrical resistor element is switched-in in order to limit the discharging current to a stipulated maximum current, in particular to a maximum current value. By the limitation of the maximum current to a stipulated current or current value, in particular, an electrochemical “jolting” of the at least one battery cell can be counteracted. In particular, a controlled deep discharging process can be achieved. Additionally, any unwanted heat-up, and ageing processes associated therewith, can be counteracted.

Appropriately, the discharging device comprises the resistor element. The resistor element can be an element of a working device or of a charging device. The working device can be an electric processing tool.

According to a further configuration of the second aspect of the invention, the method comprises a step cb), according to which a switch-out of the electrical resistor element and/or an adjustment of an electrical resistance value of the electrical resistor is executed, immediately the discharging current undershoots a stipulated threshold value. Appropriately, the resistance value can be successively reduced, in particular to the extent of an electrical short-circuit. By means of the switch-out and/or adjustment according to step cb), in particular, a discharge voltage for discharging the electric battery cell can be accelerated.

According to a further configuration of the second aspect of the invention, for the switch-in and/or for the switch-out of the resistor element, an electric switching device of the discharging device is employed. Alternatively or additionally, for the switch-in and/or for the switch-out of the resistor element, the electric switching device of the discharging device is actuated, particularly in accordance with the discharging current and/or automatically.

According to a further configuration of the second aspect of the invention, the battery pack comprises two electric poles. In particular, the poles of the battery pack are configured to be accessible from the exterior. Between the poles of the battery pack, an electric pole voltage of the battery pack, which pole voltage is dependent upon an electric cell voltage of the at least one electric battery cell, is deployed or applied, or is present. Steps ab) and bb), in particular, and step cb) are executed until such time as the electric pole voltage lies within a stipulated range around 0 V (volts). The above-mentioned stipulated range around 0 V can extend from a minimum of −0.1 V to a maximum of 1.0 V. Appropriately, for the stipulated range around 0 V, the limiting values thus indicated are not included in the range.

Appropriately, the stipulated range around 0 V is defined such that the lower limiting value thereof corresponds to 0 V, or is lower than 0 V, whereas the upper limiting value thereof lies below a stipulated end-of-discharge voltage value, in particular of other and/or of conventional battery cell types.

Appropriately, in particular by means of a display device, an external indication can be delivered as to whether the pole voltage lies within the range around 0 V.

Appropriately, the pole voltage can be dependent upon the electric cell voltage of all the battery cells of the battery pack, particularly in the event that the battery cells of the battery pack, vis-à-vis the poles of the battery pack, are arranged in a parallel electric circuit or in a serial electric circuit.

Appropriately, it can be contemplated that one group of electrically parallel-connected battery cells is electrically arranged in series with another group of electrically parallel-connected battery cells. Alternatively or additionally, it can be contemplated that one group of electrically series-connected battery cells is electrically arranged in parallel with another group of electrically parallel-connected battery cells. For the pole voltage, optionally, a different range around 0 V can be defined, the limits of which are dependent upon the mutual interconnection of battery cells.

Under certain circumstances, in the interests of more rapid or more controlled discharging, or for the reliable removal of all charges from the at least one deep discharge-proof battery cell of the battery pack, an application of an additional electric voltage or counter-voltage to the poles can be executed. Under certain circumstances, in this manner, subsequent relaxation effects can be counteracted. In particular, the comparative term “more controlled” can be understood in the sense of “particularly controlled” and/or “in a particularly orderly manner”.

According to a further configuration of the second aspect of the invention, the electric discharging current is logged over a discharge period. Values of the discharging current are logged over the discharge period. On the basis of the logging of the discharging current over the discharge period, a remaining residual quantity of charge in the at least one battery cell can be determined. In this manner, it can be particularly reliably ascertained whether the at least one deep discharge-proof battery cell has actually executed the transition to the state of deep discharge, or otherwise.

According to a further configuration of the second aspect of the invention, the remaining and/or instantaneously remaining residual quantity of charge in the at least one battery cell is determined. To this end, the prevailing electric pole voltage between the poles of the battery pack is monitored. On the basis of the monitoring of the pole voltage, particularly in combination with the above-mentioned monitoring of the discharge current, the residual quantity of charge thus determined, in particular a specific value of the residual quantity of charge thus determined, can be plausibilized. The reliability of deep discharging can thus be enhanced.

According to a further configuration of the second aspect of the invention, energy released upon the discharging of the at least one battery cell can be delivered to another load and/or to another energy storage device. Accordingly, energy extracted from the at least one battery cell in conjunction with deep discharging can be at least partially utilized.

According to a further configuration of the second aspect of the invention, the discharging device is a component of the battery pack. Alternatively, the discharging device can be configured separately from the battery pack and, in particular exclusively for the execution of steps ab) and bb), in particular, and of step cb), is detachably electrically connected to the poles of the battery pack. Alternatively, the discharging device can be a component of an electric charging device which is detachably connected to the battery pack for the electric charging and/or discharging of the at least one battery cell of the battery pack. Alternatively, the discharging device can be a component of an electric processing tool which is detachably connected to the battery pack, wherein the electric processing tool is operable by means of electrical energy which is extracted from the battery pack.

A battery pack according to the second aspect of the invention is configured for a method according to the second aspect of the invention, within the meaning of the preceding description, and comprises an, in particular, electronic control and/or regulation device. The control and/or regulation device of the battery pack is appropriate for actuating an electric discharging device for the execution of the method. The discharging device which is actuatable by means of the control and/or regulation device can either be a component of the battery pack, or is not a component of the battery pack.

An electric processing tool according to the second aspect of the invention comprises a location device for the interchangeable location, and thus for the associated electrical connection of a battery pack for the execution of a method according to the second aspect of the invention, as described above. The electric processing tool moreover comprises a discharging device, which device is configured for executing the method according to the second aspect of the invention. Alternatively or additionally, the electric processing tool comprises an, in particular, electronic control and/or regulation device, which device is appropriate for actuating the discharging device for the execution of the method according to the second aspect of the invention.

An electric charging device according to the second aspect of the invention comprises a location device for the interchangeable location, and thus for the associated electrical connection of a battery pack for the execution of a method according to the second aspect of the invention, as described above. The charging device moreover comprises a discharging device, which device is configured for executing the method according to the second aspect of the invention. Alternatively or additionally, the charging device comprises a control and/or regulation device, which device is appropriate for actuating the discharging device for the execution of the method.

A system according to the second aspect of the invention comprises a battery pack according to the second aspect of the invention, as described above. The system moreover comprises an electric processing tool according to the second aspect of the invention and/or an electric charging device according to the second aspect of the invention, as described above.

In particular, it is intended that the second aspect of the present invention does not initiate any permanent and, in particular, non-reversible introduction of a state of deep discharge of the at least one battery cell. In particular, it is intended that the repeated execution of the method should be possible, or that the battery pack, further to deep discharging according to the method, is capable of further recharging and the resumption of service.

In the event of an abrupt and/or uncontrolled short-circuiting of deep discharge-proof battery cells, the cell chemistry thereof can be disturbed or unbalanced, as a result of which undesirable ageing processes or effects can be initiated. Moreover, the desired state of deep discharge cannot be reliably adjusted or achieved. Counteraction hereof is intended to be achieved by means of the second aspect of the invention.

In particular, the method enables a reliable deep discharging of the entire battery pack, in particular of all the battery cells thereof.

### Third Aspect of the Invention

One object of the third aspect of the present invention is the provision of a method for the electric charging of a battery pack, of an electric battery pack of this type, of an electric charging device for charging a battery pack, of an electric system having a battery pack of this type and having a charging device of this type, an employment of at least one deep discharge-proof battery cell in an electric battery pack and/or an employment of a battery pack and/or an employment of an electric charging device and/or an employment of an electric system, each of which in particular assumes specific, and particularly improved properties. In particular, it is intended that a customarily deliberately suppressed charging, proceeding from a state of deep discharge of at least one electric battery cell of the battery pack, is enabled by means of the invention.

A method according to the third aspect of the invention is employed for the electric charging of a battery pack. In particular, the battery pack can be electrically charged in conjunction with the execution of the method. The battery pack comprises at least one electric battery cell, which cell is configured with a deep discharge-proof design. The battery cell is configured for the rechargeable storage of electrical energy. The at least one deep discharge-proof electric battery cell is configured for reversible transition between the state of deep discharge and a charged state of the at least one battery cell. In the present context, the term “reversible” can signify that the battery cell is capable of undergoing at least ten, particularly at least 100, and more particularly at least 1,000 transition cycles between the state of deep discharge and the charged state, whilst maintaining the function thereof. Alternatively or additionally, the term “reversible” can signify the stable assumption by the battery cell of a state of deep discharge, such that the battery cell can be maintained for a prolonged period and/or stored in the state of deep discharge. The battery cell can be configured, in multiple cycles, to execute an alternating transition from the state of deep discharge to the charged state, by the charging thereof with electrical energy, and thereafter to execute a transition from the charged state back to the state of deep discharge, by the tapping of charged electrical energy. In particular, the at least one battery cell, in the state of deep discharge, is classified as essentially de-energized. The at least one electric battery cell, in the state of deep discharge, in particular, can be de-energized and/or physically short-circuited. In other words: the battery cell can assume the state of deep discharge, in the event of the de-energized state thereof. The battery pack has two electrically contact-connectable electric poles. The poles of the battery pack configured such that electric pole voltage of the battery pack, which pole voltage is dependent upon an electric cell voltage of the at least one electric battery cell, can be applied thereto. The two poles of the battery pack can be embodied as electric terminals of the battery pack. In particular, the two poles of the battery pack are configured such that the electric pole voltage of the battery pack can be tapped at the poles. For example, the poles of the battery pack can be exposed to an external environment of the battery pack. In particular, the pole voltage is defined by a potential difference between the poles. In particular, the pole voltage can only be tapped at the poles in the event that this voltage differs from 0 V (volts). In the event that the at least one deep discharge-proof electric battery cell assumes the state of deep discharge, the electric cell voltage of the at least one electric battery cell lies within a stipulated range around 0 V. In the event that the at least one deep discharge-proof electric battery cell assumes the charged state, the electric cell voltage of the at least one electric battery cell exceeds the stipulated range around 0 V.

The method according to the third aspect of the invention comprises a step ac), according to which a detection of the at least one battery cell as deep discharge-proof is executed. Alternatively or additionally, according to step ac), a detection of the state of deep discharge is executed. In particular, the term “detection of a state of deep discharge” can be understood to the effect that a detection is executed as to whether the at least one battery cell presently assumes a state of deep discharge. Detection according to step ac) can be executed by reference to predefined characteristic curves and/or by means of a battery management system of the battery pack, and/or by reference to information which is assigned to the battery pack and/or to the battery cell, wherein the information identifies the at least one battery cell as deep discharge-proof and/or identifies the state of deep discharge thereof. Information can be exemplarily communicated via an interface, and/or retrieved and/or captured. The method moreover comprises a step bc), according to which a verification of an orientation of the poles of the battery pack vis-à-vis a charging device is executed, wherein the charging device is configured for the electric charging of the at least one battery cell of the battery pack. Alternatively or additionally, according to step bc), a check of the battery pack for the presence of a malfunction is executed. The method moreover comprises a step cc), according to which—in the event that it proceeds from the check according to step bc) that the poles of the battery pack assume a stipulated charging orientation vis-vis the charging device and/or that the battery pack is free of any malfunction—an electric charging of the at least one electric battery cell is executed by means of the charging device, in particular from the state of deep discharge thereof, via the poles of the battery pack, in order to execute the electric charging of the battery pack.

In this manner—as described above—a transition of the at least one deep discharge-proof electric battery cell of the battery pack from the state of deep discharge thereof to a charged state thereof is enabled. In the case of the employment of conventional battery cells for conventional charging processes, this facility is typically not provided, particularly on the grounds that conventional battery cells, further to the deep discharge thereof, are typically classified as permanently unusable. In particular, the charged state can be a fully-charged state, or an intermediate state, which state enables a charging by means of conventional methods, or charging devices, or systems, i.e. by means of methods, or charging devices or systems, by means of which conventional battery cells can also be charged. Moreover, by means of the verification of the orientation of the poles of the battery pack vis-à-vis the charging device, optionally in the absence of the pole voltage, a target polarity of the battery pack can be established, in order to counteract any reverse polarity charging of the battery, proceeding from a state of deep discharge, or to prevent any such reverse polarity charging.

The battery pack can appropriately comprise two or more deep discharge-proof battery cells. The pole voltage of the battery cell can be dependent upon the electric cell voltages of the all the battery cells of the battery pack. The battery cells of the battery pack, vis-à-vis the poles of the battery pack, can be arranged in a parallel electric circuit or in a serial electric circuit.

Appropriately, it is contemplated that one group of electrically parallel-connected battery cells is electrically arranged in series with another group of electrically parallel-connected battery cells. Alternatively or additionally, it is also contemplated that one group of electrically series-connected battery cells is electrically arranged in parallel with another group of electrically parallel-connected battery cells. Alternatively or additionally, composite arrangements are optionally contemplated.

Appropriately, the electric pole voltage, in the event that the battery pack comprises only a single battery cell, in the state of deep discharge thereof, lies within the stipulated range around 0 V, whereas the electric pole voltage, in the charged state, exceeds the stipulated range around 0 V. In the event that the battery pack comprises more than one battery cell, for the pole voltage, limiting values of a different range around 0 V can be dependent upon the mutual interconnection of battery cells.

According to one configuration of the third aspect of the invention, step bc) comprises an injection of at least one electric current pulse, by means of the charging device, via the two poles of the battery pack, into the at least one battery cell of the battery pack. This injection can enable a particularly rapid check.

A value of the current pulse can lie between C/100 and 1000 C, in particular between C/2 and 5 C. The duration of pulse energization can exemplarily lie between 1 ms and 10 h, preferably between 10 s and 30 s. Current pulses are not necessarily constant, and can assume various forms, in particular a square-wave form or a sinusoidal form. Between two sequential current pulses, a relaxation phase of up to several days can occur, in particular between 30 s and 1 h.

According to a further configuration of the third aspect of the invention, for the verification of the orientation of the poles vis-à-vis the charging device, an electric voltage response of the at least one battery of the battery pack to the current pulse is captured. Alternatively or additionally, for the checking of the battery pack for the presence of a malfunction, an internal electrical resistance of the battery pack, and/or an electrical capacity of the battery pack, and/or a value for a thermal characteristic of the battery pack, and/or a value for a decay characteristic of operating signals of the battery pack, and/or a rate of diffusion of electrically charged particles of the at least one battery cell of the battery pack is determined on the basis of the current pulse. Appropriately, the term “determination” can be understood in the sense of “ascertainment” and/or “measurement”.

According to a further configuration of the third aspect of the invention, for the execution of step bc), an internal electronic battery management system of the battery pack is employed and—alternatively or additionally—is activated. The internal electronic battery management system of the battery pack accesses an internal electronic memory device of the battery pack. The internal electronic memory device of the battery pack is configured for saving at least one memory input which is representative of a malfunction. In this manner, by the read-out of the electronic memory device by means of a battery management system, a check can be executed as to whether a malfunction has occurred previously, and/or whether this malfunction is still in force. The battery management system can be configured to inhibit the battery pack, in the event of the read-out of malfunction. If the supply voltage of the battery management system has assumed an excessively low level, such that no continuous monitoring has been executed, a malfunction can be saved.

The battery pack can appropriately comprise an auxiliary energy storage device which is independent of the at least one deep discharge-proof electric battery cell. The battery management system of the battery pack and—alternatively or additionally—the internal electronic memory device of the battery pack can thus be supplied with electrical energy by means of the auxiliary energy storage device, in order to enable the detection and, in particular, the logging of the occurrence of a malfunction in the event of a state of deep discharge of the at least one battery cell. In this manner, a continuation of malfunction monitoring during the state of deep discharge can be enabled. The auxiliary energy storage device can be an integrated secondary battery. Alternatively, malfunction monitoring can also be executed passively, i.e. particularly in the absence of any power or energy supply, e.g. by means of a fusible link.

The battery pack and the charging device appropriately comprise complementary communication connection devices. Further appropriately, the communication connection devices of the battery pack and of the charging device are mutually coupled in the context of the method, in order to generate a communication connection between the battery pack and the charging device. In particular, in this manner, the battery management system and/or the electronic memory device can be mutually coupled to the charging device for the transmission of data or for the exchange of information. Appropriately, the battery management system, by means of the communication connection or by means of an additional electrical conductor, can be supplied with a voltage for the activation thereof.

According to a further configuration of the third aspect of the invention, in conjunction with the execution of step cc), the battery pack is charged by means of the charging device according to a stipulated charging profile. In particular, further to charging according to the stipulated charging profile, the pole voltage is measured, in order to compare a resulting actual value of the pole voltage with a target value of the pole voltage which is anticipated for the charging profile. The charging of the battery pack is thus interrupted, in the event that the actual value deviates from the target value by more than a stipulated tolerance margin. The charging profile can enable a stepped charging and a subsequent comparison of the notional state-of-charge (SoC) in comparison with the measured state-of charge, on the basis of the pole voltage.

Appropriately, charging at the commencement of a charging process can be pulsed, or can be executed with a continuous electric current. The current can thus be constant, or can be flexibly adjusted by reference to a set of characteristics or a function. The electric voltage and/or temperature during charging can be monitored. Optionally, pauses and/or interruptions or countercharging can be incorporated in a charging protocol. Potential rates of charging, in particular, are C/1000 to 1000 C.

According to a further configuration of the third aspect of the invention, in conjunction with the execution of step bc), a check is executed as to whether the poles of the battery pack are electrically short-circuited. Alternatively or additionally, electric charging of the battery pack in the context of step cc) is only executed in the event that the poles of the battery pack are not electrically short-circuited.

Appropriately, for the verification of the battery pack for the presence of a malfunction, a passive and/or off-circuit fault-sensitive device of the battery pack can be employed. The device can comprise a diode or another passive component.

According to a further configuration of the third aspect of the invention, for the execution of step bc), complementary connection profiles of the battery pack and of the charging device can be employed. The direction of charging by means of the complementary charging profiles is mechanically encoded such that the poles of the battery pack are only electrically connectable and/or connected to the charging device in the direction of charging. Complementary charging profiles can be embodied according to the lock-and-key principle, also generally known to a person skilled in the art under the term “poka-yoke principle”.

According to a further configuration of the invention, the at least one and, in particular, each battery cell of the battery pack is configured as electrically reversible. Alternatively or additionally, the at least one and, in particular, each battery cell of the battery pack is a sodium-ion battery cell, in particular having an aprotic electrolyte, and/or a solid-state electrolyte battery cell.

Alternatively or additionally, the at least one and, in particular, each battery cell of the battery pack is appropriately selected from the group comprised of the following: sodium-ion battery cells, in particular having an aprotic and, more particularly, having a fluid electrolyte; solid-state electrolyte battery cells, in particular having lithium ions and/or having sodium ions; lithium-ion battery cells having copper-free current collectors, in particular having non-metallic current collectors and/or having no anode and/or having a lithium metal electrode. Such cell types can be particularly stable and/or robust in response to cyclical deep discharging.

Appropriately, the stipulated range of the cell voltage around 0 V extends from −1 V to 1.5 V, particularly from 0 V to 1 V, and more particularly from 0 V to 0.1 V. Appropriately, for the stipulated range around 0 V, the limiting values thus indicated, and which differ from 0 V, are not included in the range. Alternatively or additionally, the stipulated range around 0 V can be defined such that the lower limiting value thereof corresponds to 0 V, or is lower than 0 V, whereas the upper limiting value thereof lies above a stipulated end-of-discharge voltage value, in particular of other and/or of conventional battery cell types. In particular, the above-mentioned values apply to individual cells such that, depending upon the number of battery cells and/or the interconnection thereof, optionally, ranges having quantitatively higher limiting values for the pole voltage of the battery pack can also be generated. Optionally, the range around 0 V, alternatively to the above-mentioned definition thereof by reference to the pole voltage, can also be defined by reference to the state-of-charge (SoC) wherein, in this case, the limits of the range, in particular, can be a 0% SoC and a 20% SoC.

In some cell types, further to short-term deep discharging, a voltage relaxation can occur, as a result of which a further rise in the pole voltage is automatically generated. A voltage relaxation of this type can be at least partially counteracted, wherein the state of deep discharge of the battery cell is maintained over a longer term, in particular for a stipulated time interval. Correspondingly, in the present context, it can be appropriate to monitor a maintenance time of the state of deep discharge and/or to consider this maintenance time in the context of identification.

Appropriately, in the present context, the term “deep discharge” can be understood as a state proceeding from the tapping of current up to the achievement of a virtually complete transfer of current carriers from a negative pole (anode) to a positive pole (cathode) of the cell, or up to the achievement of a very low residual quantity of electrochemical energy. Alternatively or additionally, the term “deep discharge” can be understood as a state proceeding from the tapping of current to the undershoot of a specific electric voltage, which voltage corresponds to an end-of-discharge voltage of conventional battery cells. By way of particular distinction from conventional battery cell types, in the case of the at least one deep discharge-proof battery cell, a singular and, in particular, multiple deep discharging is enabled, with no functional impairment.

Alternatively or additionally, reference can appropriately be made to presently widespread and colloquial definitions, c.f. https://de.wikipedia.org/wiki/Tiefentladung (deep discharge) and https://de.wikipedia.org/wiki/Elektrische_Kapazität (electrical capacity)—each in the version thereof as at Jan. 15, 2025. According thereto, the term “deep discharge” can be understood as a state proceeding from the tapping of current up to a near-exhaustion of capacity or up to the achievement of a specific voltage—with the proviso that, in the case of accumulators and batteries, the term “capacity” can be employed to describe the maximum quantity of charge which can be stored therein. This “capacity”, which is expressed in ampere-hours (represented by the symbol Ah), bears no relation to electrical capacitance, which is a physical variable employed in the field of electrostatics.

Appropriately, the at least one battery cell of the battery pack can be configured, with no breakdown of the cell components thereof, in particular of the cell electrodes thereof, to undergo a deep discharge. Alternatively or additionally, at least one of the cell electrodes of the at least one battery cell of the battery pack can incorporate a graphite material, or can be comprised of such a graphite material.

Appropriately, the at least one electric battery cell of the battery pack has at least one and, in particular, only one copper-free current collector. A current collector of this type can be incorporated in a respective cell electrode of the battery cell, or can comprise the respective cell electrode.

Appropriately, as indicated above, the at least one battery cell of the battery pack, which cell is configured for reversible deep discharging, is a solid-state battery cell. A solid-state battery of this type, in particular, comprises electrolytes which, under standard conditions, are solid.

Under certain circumstances, it can be appropriate that none of the electric battery cells of the battery pack is a conventional lithium-ion battery cell. Alternatively or additionally, in particular, none of the battery cells of the battery pack is a conventional nickel-metal hydride battery cell. In other words: it can be appropriate that the at least one battery cell of the battery pack corresponds to a cell type, which cell type differs from conventional lithium-ion battery cells and/or from conventional nickel-metal hydride battery cells.

Appropriately, the battery pack is an electric accumulator pack. The at least one battery cell can be an electric accumulator cell.

An electric battery pack according to the third aspect of the invention, which electric battery pack, in particular, is configured for interchangeable electrical connection with an electric processing tool, comprises at least one deep discharge-proof electric battery cell, which electric battery cell is configured for the storage of electrical energy. The battery pack moreover comprises two electrically contact-connectable poles, which poles are configured to apply an electric pole voltage of the at least one battery cell which is dependent upon an electric cell voltage of the at least one electric battery cell. The battery pack is configured and/or is appropriate for executing a method according to the third aspect of the invention, as described above.

An electric charging device according to the third aspect of the invention is employed for the electric charging of a battery pack, in particular for charging a battery pack according to the third aspect of the invention, as described above. The charging device comprises a connection device for the electrical connection of the charging device to the battery pack which is to be charged. The charging device is moreover configured and/or is appropriate for executing a method according to the third aspect of the invention, as described above.

An electric system according to the third aspect of the invention comprises an electric battery pack, as described above, and an electric charging device, as described above. The battery pack and the charging device are mutually tailored for executing a method according to the third aspect of the invention, as described above.

According to the third aspect of the invention, at least one deep discharge-proof battery cell is employed in a battery pack according to the third aspect of the invention, within the meaning of the preceding description. Alternatively or additionally, the electric battery pack according to the third aspect of the invention is employed for executing an above-mentioned method according to the third aspect of the invention. Further alternatively or additionally, an electric charging device according to the third aspect of the invention, as described above, is employed for executing an above-mentioned method according to the third aspect of the invention. Further alternatively or additionally, an electric system according to the third aspect of the invention, as described above, is employed for executing an above-mentioned method according to the third aspect of the invention.

Further advantages and features of the invention proceed from the claims and from the following description of preferred embodiments of the invention, which embodiments are represented with reference to the drawing. Identical reference symbols describe identical, similar or functionally equivalent components.

It is understood that the above-mentioned features, and those described hereinafter, are not only applicable in the respectively indicated combination, but also in other combinations or in isolation, without departing from the scope of the present disclosure.

### BRIEF DESCRIPTION OF THE DRAWINGS

FIG. 1 shows a rough schematic layout of one embodiment of a processing system according to one aspect of the invention, which system comprises one embodiment of an electric battery pack according to the first aspect of the invention, having at least one electric battery cell, the state of deep discharge of which is identified by the execution of one embodiment of a method according to the first aspect of the invention, by means of an identification device;

FIG. 2 shows a schematic perspective representation of one embodiment of an electric charging device according to the first aspect of the invention, for the processing system according to FIG. 1;

FIG. 3 shows a schematic side view of one embodiment of a battery electric processing tool according to the first aspect of the invention, for the electric processing system according to FIG. 1, and

FIG. 4 shows a flow diagram for a further embodiment of the method according to the first aspect of the invention;

FIG. 5 shows a layout of one embodiment of a system according to a second aspect of the invention, having one embodiment of a battery pack according to the second aspect of the invention and having one embodiment of an electric processing tool and/or an electric charging device according to the second aspect of the invention, in conjunction with the execution of one embodiment of a method according to the second aspect of the invention for the deep electric discharging of at least one deep discharge-proof electric battery cell of the battery pack;

FIG. 6 shows a layout of a further embodiment of the system according to the second aspect of the invention, in conjunction with the execution of a further embodiment of the method according to the second aspect of the invention;

FIG. 7 shows a schematic side view of a further embodiment of the system according to the second aspect of the invention;

FIG. 8 shows a schematic perspective representation of a further embodiment of the electric charging device according to the second aspect of the invention, in particular for the expansion of the system according to FIG. 3; and

FIG. 9 shows a flow diagram for a further embodiment of the method according to the second aspect of the invention;

FIG. 10 shows a rough schematic layout of one embodiment of an electric system according to a third aspect of the invention, which system comprises one embodiment of an electric battery pack according to the third aspect of the invention, and one embodiment of an electric charging device according to the third aspect of the invention, in conjunction with the execution of one embodiment of a method according to the third aspect of the invention for the electric charging of the battery pack;,

FIG. 11 shows a schematic side view of the charging device according to FIG. 10;

FIG. 12 shows a schematic side view of the battery pack according to FIG. 10;

FIG. 13 shows a rough schematic layout of a further embodiment of the electric system according to the third aspect of the invention;

FIG. 14 shows a schematic side view of a further embodiment of the electric battery pack according to the third aspect of the invention, in an interchangeably electrically connected state to an electric processing tool; and

FIG. 15 shows a flow diagram for one embodiment of the method according to the third aspect of the invention.

### DETAILED DESCRIPTION OF EXEMPLARY EMBODIMENTS OF THE FIRST ASPECT OF THE INVENTION

An electric processing system 11a comprises a battery-electric processing tool 4a and—alternatively or additionally—an electric charging device 5a. The processing system 11a moreover comprises a battery pack 1a, which pack is chargeable for the storage of electrical energy by means of the electric charging device 5a and—alternatively or additionally—is dischargeable, in particular for the deep discharging thereof, by the tapping of stored electrical energy for the supply of the processing tool 4a. The processing tool 4a is exemplarily configured as a chainsaw, in particular having a rotationally drivable saw chain. In the present case, the battery pack 1a is configured for detachable electrical connection to the processing tool 4a and/or to the charging device 5a. In the present case, the battery pack 1a is interchangeably configured.

The battery pack 1a comprises at least one and, in particular, multiple electric battery cells 2a. The at least one electric battery cell 2a of the battery pack 1a can assume a state of deep discharge, in which state it is as least essentially classified as de-energized. The battery cell 2a can moreover assume a charged state which differs from the state of deep discharge, into which state it can execute a transition from the state of deep discharge, in the context of a charging process. The battery cell 2a is configured for a reversible transition between the state of deep discharge and the charged state, in particular i.e. the battery cell 2a can undergo cyclical deep discharging and recharging.

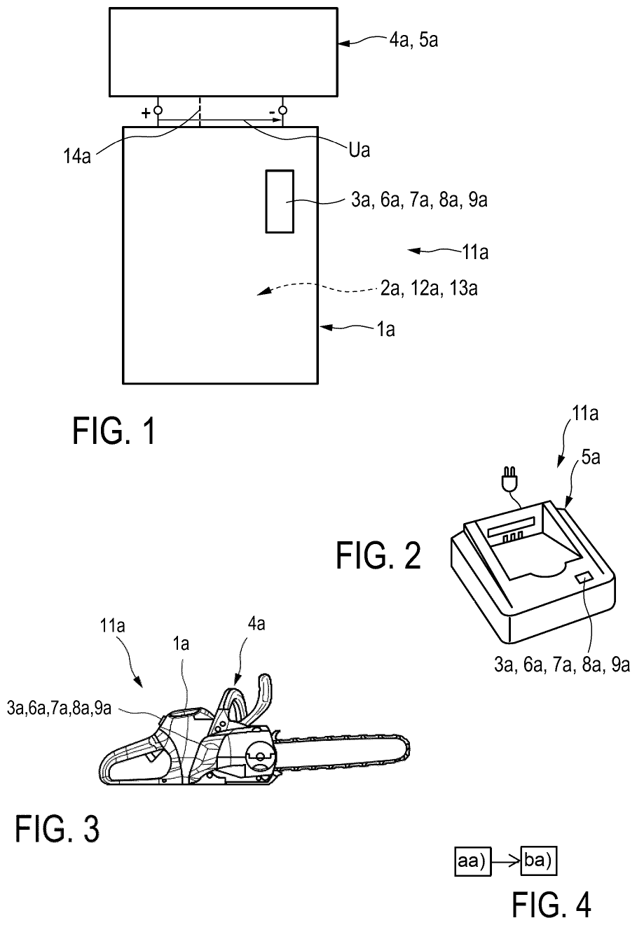

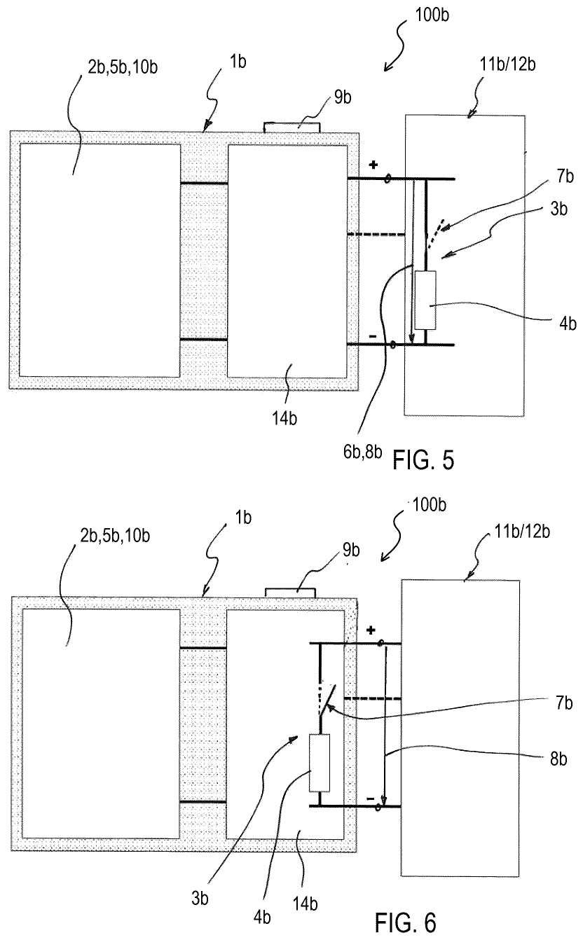

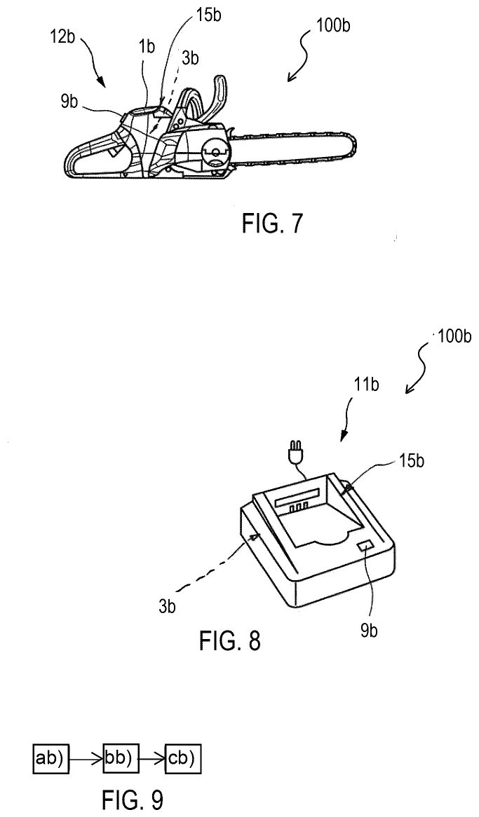

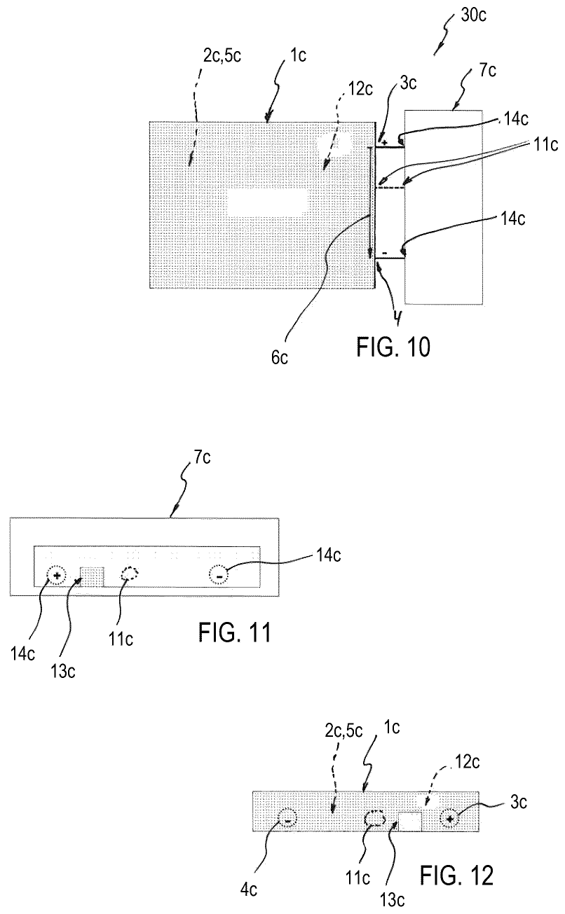

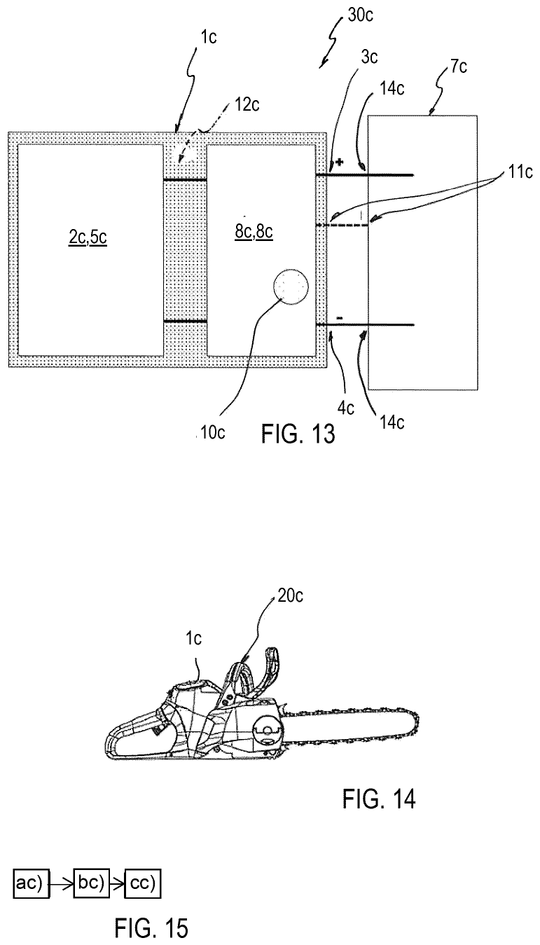

The battery pack 1a comprises two poles, the electric polarity of which, in the illustration according to FIG. 1, is identified by the corresponding symbols “+” (plus) and “−” (minus). At the two poles +, − of the battery pack 1a, an electric pole voltage Ua of the battery pack 1a is applied. The electric pole voltage Ua, which voltage can be externally tapped via the poles +, − of the battery pack 1a, is dependent, in particular directly, upon an electric cell voltage of the at least one electric battery cell 2a.

The assumption by the at least one battery cell 2a of the state of deep discharge can be identified by means of a method. This method comprises a step aa), according to which the electric pole voltage Ua of the battery pack 1a is captured and, in particular, is tapped. The method moreover comprises a step ba), according to which the state of deep discharge of the at least one battery cell 2a is identified, in particular automatically, by means of an identification device 3a, in the event that the electric pole voltage Ua thus captured lies within a stipulated range around 0 V.

The stipulated range around 0 V is exemplarily defined such that the lower limiting value thereof corresponds to 0 V, or lies below 0 V, whereas the upper limiting value thereof lies below a stipulated end-of-discharge voltage value, in particular of different and/or of conventional battery cell types. The electric battery cell 2a of the battery pack 1a can repeatedly undergo essentially complete discharging.

The stipulated range around 0 V exemplarily extends from a minimum of −1 V to a maximum of 1.5 V, in particular from a minimum of 0 V to a maximum of 1 V, and more particularly from a minimum of 0 V to a maximum of 0.1 V.

In the event that the electric pole voltage Ua captured in conjunction with the execution of step aa) lies within the stipulated range around 0 V, it can be identified, in conjunction with the execution of step ba), that all the battery cells 2a of the battery pack 1a presently assume a state of deep discharge. In this case, the battery pack 1a as a whole can be described as assuming a state of deep discharge.

Step aa) is exemplarily executed at least twice. Step aa) can be repeated at an interval of 1 s, in particular of 5 s, and more particularly of 1 min. It is contemplated that step aa) is sequentially executed exactly twice, three times, or even ten times, wherein the state of deep discharge is only identified in the event that all the sequentially determined pole voltage values lie within the stipulated range around 0 V.

Pole voltage values for the pole voltage Ua are exemplarily logged and evaluated. By the logging and evaluation of pole voltage values, a check can be executed as to whether the pole voltage Ua has continuously, or only temporarily assumed a value in the stipulated range around 0 V.

Exemplarily, the identification device 3a is permanently electrically connected to the at least one battery cell 2a of the battery pack 1a. The identification device 3a—as per the present case—can be a component of the battery pack 1a. For step aa) of the method, the pole voltage Ua can be captured by means of the identification device 3a.

Alternatively of additionally, the battery pack 1a, for the execution of step aa), can be detachably electrically connected to the battery-electric processing tool 4a. The processing tool 4a can comprise the identification device 3a, in particular additionally to the identification device 3a of the battery pack 1a or in place of the identification device 3a of the battery pack 1a.

Further alternatively or additionally, the battery pack 1a, for the execution of step aa) can be detachably electrically connected to the charging device 5a. The charging device 5a can comprise the identification device 3a, in particular additionally to the identification device 3a of the battery pack 1a or in place of the identification device 3a of the battery pack 1a. It can be contemplated that the charging device 5a communicates by means of a communication connection 14a with the identification device, in particular of the battery pack 1a, or of an unrepresented standalone identification device, for the identification of the state of deep discharge.

The identification device 3a exemplarily comprises an electrically controllable display device 6a, by means of which the state of deep discharge is identified. The display device 6a can comprise an electrophoretic display 7a and/or an LED 8a. The display device 6a can be configured for the external visual indication of the state of deep discharge. Under certain circumstances, the display device 6a, in the state of deep discharge, can constitute and/or provide a passive display 9a.

The method can comprise a further step ca), according to which an electrical connection between the at least one battery cell 2a and the identification device 3a is checked, in particular for the integrity thereof.

The at least one electric battery cell 2a of the battery pack 1a is exemplarily configured as deep discharge-proof. Alternatively or additionally, the at least one electric battery cell 2a of the battery pack 1a is configured as electrically reversible, in particular as fully reversible.

Exemplarily, the at least one and, in particular, each battery cell 2a of the battery pack 1a is a sodium-ion battery cell 12a. The sodium-ion battery cell 12a can comprise an aprotic electrolyte. In particular, the sodium-ion battery cell 12a can comprise an aqueous electrolyte.

In the present case, no battery cell 2a of the battery pack 1a is a lithium-ion battery cell and/or a nickel-metal hydride battery cell.

The battery pack 1a is configured for executing the method. The processing tool 4a is configured for executing the method. The charging device 5a is configured for executing the method.

In the present case, the battery pack 1a, the processing tool 4a and the charging device 5a of the electric processing system 11a are mutually tailored and/or adapted for the execution of the method.

### DETAILED DESCRIPTION OF EXEMPLARY EMBODIMENTS OF THE SECOND ASPECT OF THE INVENTION

An electric battery pack 1b comprises at least one electric battery cell 2b, which cell is configured as deep discharge-proof. The battery cell 2b is exemplarily configured to execute a reversible transition from a state of charging thereof with electrical energy to a state of deep discharge. In particular, for the reliable deep electric discharging of the at least one deep discharge-proof electric battery cell 2b of the battery pack, a method is provided. According to the method, the battery cell 2b of the battery pack 1b can undergo deep electric discharging by means of an electric discharging device 3b, and can thus assume a state of deep electric discharge.

The method for reliable deep electric discharging by means of the electric discharging device 3b comprises a step ab), according to which the discharging device 3b is switched on. The discharging device 3b is switched on such that electric discharging current 6b, which current is based upon an electric cell voltage 5b of the at least one battery cell 2b, flows through the switched-on discharging device 3b.

The method moreover comprises a step bb), according to which a monitoring is executed as to whether the discharging current 6b falls below a stipulated level. The discharging current 6b can exemplarily be monitored, in order to identify and/or to detect that the discharging current 6b falls below, or has fallen below the stipulated level.

Exemplarily, in conjunction with the switch-on of the discharging device 3b according to step ab), an electrical resistance element 4b is switched-in, such that the discharging current 6b flows through the resistance element 4b. The switch-in of the electrical resistance element 4b is executed such that the discharging current 6b is limited to a stipulated maximum current value. In particular, the resistance element 4b is a component of the discharging device 3b.

The method exemplarily comprises a further step cb), according to which the electrical resistance element 4b is switched-out. Alternatively or additionally, according to step cb), an electrical resistance value of the resistance element 4b is adjusted. The switch-out of the electrical resistance element 4b and/or the adjustment of the electrical resistance value of the resistance element 4b is/are executed according to step cb), immediately the discharging current 6b undershoots a stipulated threshold value. The stipulated threshold value for the discharging current 6b can indicate that deep discharging has actually been achieved.

The discharging device 3b exemplarily comprises an electric switching device 7b. The electric switching device 7b is exemplarily employed for the switch-in and/or switch-out of the resistance element 4b. Alternatively or additionally, the electric switching device 7b is actuated in order to switch-in and/or switch-out the resistance element 4b. The switching device 7b can be actuated for the switch-in and/or switch-out of the resistance element 4b, for example in accordance with the discharging current 6b and—alternatively or additionally—can be automatically actuated.

The resistance value of the electrical resistance element 4b can be controllable or successively reducible, to the extent of an electrical short-circuit. Alternatively or additionally, a pulsed switch-in and/or switch-out can be executed by means of a MOSFET, in combination with an electric coil, by means of a PTC resistor, a varistor, a rheostat, or similar.

In the present case, the battery pack 2b has two electric poles +, − (plus, minus). Steps ab) und bb) in particular, and also step cb), can be executed until an electric pole voltage 8b which prevails between the poles +, − of the battery pack 1b lies within a stipulated range around 0 V. The range around 0 V can extend from a minimum of −0.1 V up to a maximum of 1.0 V.

Exemplarily, an external indication is delivered, in particular for a user, as to whether the pole voltage 8b lies within the range around 0 V. To this end, a display device 9b can be provided. The display device 9b can be embodied by an interface of the battery pack 1b and/or of the processing tool 12b and/or of the charging device 11b. Alternatively or additionally, the display device 9b can be a light-emitting diode (LED). It is alternatively or additionally contemplated that voltage sockets are provided, at which individual cell voltages and/or the pole voltage of the battery pack can be measured, in particular for optional confirmation to the effect that no contact loss is in force. For the purposes of measurement at the voltage sockets, for example, a short-term countercharging and/or a resistance or impedance measurement can be executed.

The discharging current 6b is exemplarily logged over a discharge period. On the basis of the resulting logging of the discharging current 6b over the discharge period, a remaining, or presently remaining residual quantity of charge 10b of electrical energy in the at least one battery cell 2b can be determined.

Exemplarily, a determination of the remaining residual quantity of charge 10b in the at least one battery cell 2b and a monitoring of the electric pole voltage 8b prevailing between the poles +, − of the battery pack 2b are executed, in particular in the above-mentioned manner. Moreover, on the basis of the monitoring of the pole voltage 8b, a plausibilization of the residual quantity of charge 10b thus determined can be executed.

Exemplarily, energy released in conjunction with the discharging of the at least one battery cell 2b is supplied to another load and/or to another energy storage device.

The discharging device 3b can be, for example, a component of the battery pack 1b. Alternatively, the discharging device 3b can be configured separately from the battery pack 1b and, in particular exclusively, is only detachably electrically connected to the poles +, − of the battery pack 1b for the execution of the method.

The discharging device 3b which is configured separately from the battery pack 1b can be, for example, a component of an electric charging device 11b which is detachably connected to the battery pack 1b, wherein the charging device 11b is configured for the electric charging and/or discharging of the at least one battery cell 2b of the battery pack 1b. Alternatively, the discharging device 3b which is configured separately from the battery pack 1b can be, for example, a component of an electric processing tool 12b which is detachably connected to the battery pack 1b, wherein the electric processing tool 12b is configure to operate by means of electrical energy which is extracted from the battery pack 1b.

The battery pack 1b can be an element of a system 100b which, additionally to the battery pack 1b, comprises the electric processing tool 12b and/or the electric charging device 11b.

The system 100b can moreover comprise a standalone discharging device 3b for the execution of the method. Alternatively or additionally, at least one element selected from the battery pack 1b, the electric processing tool 12b and/or the electric charging device 11b can comprise an integrated discharging device 3b. It is contemplated that the system 100b comprises multiple discharging devices 3b, which devices are mutually functionally complementary and/or are at least partially functionally redundant with respect to one another.

In the present case, the battery pack 1b comprises a control and/or regulation device 14b. The control and/or regulation device 14b can be appropriate and, in particular, can be programmed for actuating a discharging device 3b for the execution of the method. The discharging device 3b which is actuatable by means of the control and/or regulation device 14b of the battery pack 1b can either be a component of the battery pack 1b, or can be a component other than a component of the battery pack 1b.

The electric processing tool 12b and—alternatively or additionally—the electric charging device 11b exemplarily comprises a location device 15b, which device is configured for the interchangeable location of the battery pack 1b. In conjunction with the interchangeable location of the battery pack in the location device 15b, an electrical connection of the battery pack 1b to the electric processing tool 12b and/or to the electric charging device 11b can be executed.

The electric processing tool 12b and/or the electric charging device 11b can moreover comprise a discharging device 3b, which device is configured for executing the method. Alternatively or additionally, the electric processing tool 12b and/or the electric charging device 11b can comprise a control and/or regulation device 14b, which device is appropriate and, in particular, is programmed for actuating a discharging device 3b for the execution of the method.

Under certain circumstances, in the interests of more rapid or more controlled discharging, or for the reliable removal of all charges from the battery cell 2b, an application of an additional electric voltage or counter-voltage can be executed. Under certain circumstances, in this manner, subsequent relaxation effects can be counteracted.

### DETAILED DESCRIPTION OF EXEMPLARY EMBODIMENTS OF THE THIRD ASPECT OF THE INVENTION

A method according to the third aspect of the invention is provided for the electric charging of a battery pack 1c. The battery pack 1c for the method comprises at least one deep discharge-proof electric battery cell 2c. The at least one deep discharge-proof electric battery cell 2c is chargeable for the storage of electrical energy. The at least one deep discharge-proof electric battery cell 2c is configured to execute a reversible transition between a state of deep discharge and a charged state. The battery pack 1c can comprise a plurality of deep discharge-proof electric battery cells 2c. The state of deep discharge can be advantageous for a storage of the battery pack 1c and/or for a transport of the battery pack 1c, in particular by air freight. The battery cell 2c can assume, for example, a prismatic external shape.

The battery pack 1c has two externally electrically contact-connectable poles 3c, 4c. The poles 3c, 4c of the battery pack 1c are configured such that an electric pole voltage 6c of the battery pack 1c can be applied to the poles 3c, 4c. The electric pole voltage 6c which can be applied to the poles 3c, 4c is dependent upon an electric cell voltage 5c of the at least one electric battery cell 2c of the battery pack 1. The electric cell voltage 5c, in the state of deep discharge of the at least one electric battery cell 2c, lies within a stipulated range around 0 V. Conversely, the electric call voltage 5c, in the charged state of the deep discharge-proof electric battery cell 2c, exceeds the stipulated range around 0 V.

The method comprises a step ac), according to which the at least one battery cell 2c of the battery pack 1c is identified as deep discharge-proof. Alternatively or additionally, according to step ac), it is detected that the at least one deep discharge proof electric battery cell 2c presently assumes a state of deep discharge.

The method comprises a step bc), according to which an orientation of the poles 3c, 4c of the battery pack 1c are checked vis-à-vis a charging device 7c. The charging device 7c is configured for the electric charging of the at least one battery cell 2c of the battery pack 1c. Alternatively or additionally, according to step bc), the battery pack 1c is checked for the presence of a malfunction.

The method comprises a step cc), according to which—in the event that it proceeds, from the check according to step bc), that the poles 3c, 4c, vis-à-vis the charging device 2c, assume a stipulated charging orientation, and/or in the event that it proceeds, from the check according to step bc), that the battery pack 1c is free of any malfunction—the at least one electric battery cell 2c is electrically charged via the poles 3c, 4c, by means of the charging device 7c, in order to charge the battery pack 1c. Otherwise, charging can be inhibited.

The steps of the method are exemplarily executed in the temporal sequence ac)-bc)-cc).

In the present case, the electric battery pack 1c is configured for interchangeable electrical connection to an electric processing tool 20c which is operable by battery-electric power. The electric processing tool 20c exemplarily comprises a location device, which device is configured for the interchangeable location and associated electrical connection of the electric battery pack 1c. The electric processing tool 20c can be, for example, a robotic lawn mower or—as in the present case—an electric chainsaw. In principle, other types of electric processing tools 20c are contemplated.

In the present case, the battery pack 1c is configured and/or is appropriate for executing the method. In other words: the battery pack 1c is configured to undergo electric charging according to the method.

The electric charging device 7c which is configured for the electric charging of the battery pack 1c comprises a connection device 14c, which device is configured for the electrical connection of the charging device 7c to the battery pack 1c which is to be charged. The charging device 7c is configured and/or is appropriate for executing the method. In other words: the charging device 7c is configured for the electric charging of the battery pack 1c, in the context of the execution of the method.

The electric charging device 7c can comprise a mains plug for tapping electrical energy from an electric power supply grid. Electrical energy which is tapped by the electric charging device 7c can be modified by means of the charging device 7c and, in a modified form, for example according to a stipulated charging profile, can be relayed to the battery pack 1c, in order to execute the electric charging of the battery pack 1c.

In the present case, the battery pack 1c and the electric charging device 7c are components of an electric system 30c. The battery pack 1c and the charging device 7c are mutually tailored for the execution of the method.

Exemplarily, in conjunction with the execution of step bc) of the method, at least one electric current pulses is injected by means of the charging device 7c via the two poles 3c, 4c of the battery pack 1c into the at least one deep discharge-proof electric battery cell 2c of the battery pack 1c. For the confirmation of the orientation of the poles 3c, 4c vis-à-vis the charging device 7c, an electric voltage response of the at least one deep discharge-proof electric battery cell 2c of the battery pack 1c to the injected current pulse can be captured and/or evaluated.

Alternatively or additionally, for the checking of the battery pack 1c for the presence of a malfunction, an internal electrical resistance of the battery pack 1c can be determined on the basis of the current pulse.

Further additionally or alternatively, for the checking of the battery pack 1c for the presence of a malfunction, an electrical capacity of the battery pack 1c can be determined on the basis of the current pulse.

Further additionally or alternatively, for the checking of the battery pack 1c for the presence of a malfunction, a value for a thermal characteristic of the battery pack 1c can be determined on the basis of the current pulse. It is contemplated, in the execution of the method, that a generation of heat associated with a specific current pulse is observed by means of a temperature sensor.

Further additionally or alternatively, for the checking of the battery pack 1c for the presence of a malfunction, a value for a decay characteristic of operating signals of battery pack 1c can be determined on the basis of the current pulse.

Further additionally or alternatively, for the checking of the battery pack 1c for the presence of a malfunction, a rate of diffusion of electrically charged particles of the at least one battery cell 2c of the battery pack 1c can be determined on the basis of the current pulse.

The battery pack 1c exemplarily comprises an internal electronic battery management system 8c. The internal electronic battery management system 8c can be employed and/or activated for the execution of step bc) of the method.

The battery pack 1c exemplarily comprises an internal electronic memory device 9c, which device is configured for saving at least one memory input which is representative of a malfunction. The battery management system 8c can be employed and/or activated for the execution of step bc), in order to enable access to the internal electronic memory device 9c of the battery pack 1c. By means of access to the electronic memory device 9c, a read-out of memory inputs can be executed.

The battery pack 1c exemplarily comprises an auxiliary energy storage device 10c which is independent of the at least one deep discharge-proof electric battery cell 2c. The auxiliary energy storage device 10c can be exemplarily configured as a button cell. Exemplarily, the battery management system 8c of the battery pack 1c and/or the internal electronic memory device 9c of the battery pack 1c are supplied with electrical energy by means of the auxiliary energy storage device 10c, in order to enable the detection of a malfunction which occurs in the state of deep discharge, in the particular in the essentially de-energized state of the at least one deep discharge-proof battery cell 2c. In particular, the battery management system 8c and/or the electronic memory device 9c can be supplied with electrical energy by means of the auxiliary energy storage device 10c, in order to enable the detection and/or logging of a malfunction which occurs in the state of deep discharge.

In the present case, the battery pack 1c and the charging device 7c comprise mutually complementarily configured communication connection devices 11c. The communication connection devices 11c of the battery pack 1c and of the charging device 7c can be mutually coupled in the context of the execution of the method, in order to set-up a communication connection between the battery pack 1c and the charging device 7c. In particular, the battery management system 8c of the battery pack 1c and the charging device 7c can communicate with one another via the communication connection.

Exemplarily, in conjunction with the execution of step bc) of the method, the battery pack 1c is charged by means of the charging device 7c, according to a stipulated charging profile. The pole voltage 6c can be measured, in particular further to the execution of charging in accordance with the stipulated charging profile. On the basis of the measurement of the pole voltage 6c, a resulting and, in particular, a measured actual value of the pole voltage 6c can be compared with an anticipated target value for the pole voltage 6c. Exemplarily, the charging of the battery pack 1c can be interrupted, in the event that the actual value deviates from the target value by more than a stipulated tolerance margin.

Exemplarily, in conjunction with the execution of step bc), a check can be executed as to whether an electrical short-circuit is present between the poles 3c, 4c of the battery pack 1c. Alternatively or additionally, electric charging of the battery pack 1c in the context of step cc) can only be executed in the event that the poles 3c, 4c of the battery pack 1c are not electrically short-circuited. In other words: in the event of the detection of an electrical short-circuit between the poles 3c, 4c, electric charging of the battery pack 1c can be inhibited and/or interrupted.

The battery pack 1c can exemplarily comprise a passive and/or off-circuit fault-sensitive device 12c, which device is employed for checking the battery pack 1c for the presence of a malfunction.

The battery pack 1c and the charging device 7c exemplarily comprise complementary connection profiles 13c, which profiles are employed for the execution of step bc). The complementary connection profiles 13c are configured and/or mutually tailored for the mechanical encoding of the charging orientation. The complementary connection profiles 13c can mechanically encode the charging orientation, such that the poles 3c, 4c of the battery pack 1c are only electrically connectable and/or connected to the charging device 7c in the charging orientation. Expressed conversely, an electrical connection of the poles 3c, 4c to the charging device 7c can be mechanically obstructed, in the event that the battery pack 1c and the charging device 7c do not assume the stipulated charging orientation vis-à-vis one another.

Exemplarily, the at least one and, in particular, each battery cell 2c of the battery pack 1c is configured as electrically reversible. Alternatively or additionally, the at least one and, in particular, each battery cell 2c of the battery pack 1c can be a sodium-ion battery cell. A sodium-ion battery cell of this type can comprise an aprotic electrolyte. Alternatively or additionally, the battery cell 2c can be a solid-state electrolyte battery cell.

In the present case, at least one deep discharge-proof battery cell 2c is employed in the electric battery pack 1c. In particular, the at least one deep discharge-proof battery cell 2c in the electric battery pack 1c is employed in conjunction with the method for charging the battery pack 1c.

In the present case, the battery pack 1c is employed for executing the method for charging the electric battery pack 1c.

In the present case, the electric charging device 7c is employed for executing the method for charging the battery pack 1c.

In the present case, the electric system 30c is employed for executing the method for charging the battery pack 1c.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method for identifying a state of deep discharge of at least one electric battery cell of an electric battery pack via an identification device, wherein the battery pack comprises two poles at which an electric pole voltage of the battery pack, which voltage is dependent upon an electric cell voltage of at least one electric battery cell, is tappable, wherein the at least one battery cell is configured for a reversible transition between the state of deep discharge and a charged state of the at least one battery cell, wherein, in the state of deep discharge, the electric pole voltage lies within a stipulated range around 0 V, wherein, in the charged state, the electric pole voltage exceeds the stipulated range around 0 V,
wherein the method comprises the steps of:
aa) capturing a value of the electric pole voltage of the battery pack; and
ba) in an event that the value of the electric pole voltage captured in conjunction with the execution of step aa) lies within the stipulated range around 0 V, identifying, via the identification device, the state of deep discharge of the at least one battery cell.

2. The method according to claim 1,
wherein, in conjunction with the execution of step ba), identifying that all battery cells of the battery pack presently assume the state of deep discharge, in the event that the electric pole voltage captured in conjunction with the execution of step aa) lies within the stipulated range around 0 V.

3. The method according to claim 1,
wherein, for each execution of step aa), a pole voltage value is determined for the pole voltage, and/or
wherein step aa) is executed twice or more, within a time interval of greater than 1 min, wherein the state of deep discharge is only identified in the event that all pole voltage values thus determined lie within the stipulated range around 0 V.

4. The method according to claim 1,
wherein pole voltage values for the pole voltage are logged and evaluated, in order to execute a check as to whether the pole voltage has continuously or only temporality assumed a value within the stipulated range around 0 V.

5. The method according to claim 1,
wherein the state of deep discharge is identified by an electrically controllable display device of the identification device.

6. The method according to claim 1, wherein the method further comprises the step of:
ca) checking an electrical connection between the at least one battery cell and the identification device.

7. A method for deep electric discharging of a deep discharge-proof electric battery cell of a battery pack via an electric discharging device,
wherein the method comprises the steps of:
ab) switching-on the discharging device such that a discharging current flows through the switched-on discharging device; and
bb) checking as to whether the discharging current falls below a stipulated level.

8. The method according to claim 7,
wherein the switching-on according to step ab) comprises a switching-in of an electrical resistance element in order to limit the discharging current to a stipulated maximum current.

9. The method according to claim 8, wherein the method further comprises the step of:
cb) switching-out the electrical resistance element and/or adjusting an electrical resistance value of the resistance element immediately upon the discharging current undershooting a stipulated threshold value.

10. The method according to claim 7,
wherein the discharging current is logged over a discharge period in order to determine a remaining residual quantity of charge in the battery cell.

11. The method according to claim 10,
wherein the remaining residual quantity of charge in the battery cell is determined, and
wherein a prevailing electric pole voltage between the poles of the battery pack is monitored, for plausibility of the residual quantity of charge thus determined.

12. The method according to claim 7,
wherein energy released upon the discharging of the battery cell is delivered to another load and/or to another energy storage device.

13. A method for electric charging of a battery pack, wherein the battery pack has:
at least one deep discharge-proof electric battery cell, which battery cell is chargeable with electrical energy and is configured to execute a reversible transition between a state of deep discharge and a charged state; and
two electrically contact-connectable electric poles, which two poles are configured such that electric pole voltage of the battery pack, which voltage is dependent upon an electric cell voltage of the at least one electric battery cell, is applied thereto;
wherein the electric cell voltage, in a state of deep discharge, lies within a stipulated ranged around 0 V and, in the charged state, exceeds the stipulated range around 0 V;
wherein the method comprises the steps of:
ac) detecting the at least one battery cell as deep discharge-proof and/or detecting the state of deep discharge;
bc) checking an orientation of the two poles vis-à-vis a charging device for the electric charging of the at least one battery cell of the battery pack and/or checking of the battery pack for the presence of a malfunction;
cc) in an event that it proceeds, from the check according to step bc), that the two poles, vis-à-vis the charging device, assume a stipulate charging orientation, and/or that the battery pack is free of any malfunction, electric charging the at least one electric battery cell via the two poles, via the charging device, in order to charge the battery pack.

14. The method according to claim 13,
wherein step bc) comprises an injection of at least one electric current pulse by the charging device via the two poles of the battery pack into the at least one battery cell of the battery pack.

15. The method according to claim 14,
wherein, for confirming the orientation of the two poles vis-à-vis the charging device, an electric voltage response of the at least one battery cell to the current pulse is captured; and/or
wherein, for checking the battery pack for the presence of a malfunction, determining, based on the current pulse, at least one of:
an internal electrical resistance of the battery pack,
an electrical capacity of the battery pack,
a value for a thermal characteristic of the battery pack,
a value for a decay characteristic of operating signals of the battery pack, or
a rate of diffusion of electrically charged particles of the at least one battery cell of the battery pack.

16. The method according to claim 13,
wherein, for the execution of step bc), an internal electronic battery management system of the battery pack is employed and/or activated, which system accesses an internal electronic memory device of the battery pack for saving at least one memory input which is representative of a malfunction.

17. The method according to claim 13,
wherein, by the execution of step bc), the battery pack is charged via the charging device according to a stipulated charging profile and, the pole voltage is measured, in order to compare a resulting actual value of the pole voltage with an anticipated target value for the pole voltage, according to the charging profile,
wherein the charging of the battery pack is interrupted in the event that the actual value deviates from the target value by more than a stipulated tolerance margin.

18. The method according to claim 13,
wherein, in conjunction with the execution of step bc), a check is executed as to whether the two poles of the battery pack are electrically short-circuited, and/or
wherein electric charging of the battery pack in the context of step cc) is only executed in the event that the two poles of the battery pack are not electrically short-circuited.

19. The method according to claim 13,
wherein the at least one battery cell of the battery pack is configured as electrically reversible; and/or
wherein the at least one battery cell of the battery pack is a sodium-ion battery cell, having an aprotic electrolyte, and or is a solid-state electrolyte battery cell.

20. An electric system, comprising:
an electric battery pack; and
a battery-electric electrical processing tool and/or a charging device;
wherein the electric system is configured to execute the method according to claim 1.
